(19) United States
(12) Patent Application Publication
(10) Pub. No.: US 2008/0153731 A1
(43) Pub. Date: Jun. 26, 2008

(54) Clean chemistry composition, method of manufacturing same, and system making use of same

(76) Inventor: Mark Buehler, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/644,254

(22) Filed: Dec. 21, 2006

(51) Int. Cl. H01L 21/306; C11D 7/00

(52) U.S. Cl. 510/175; 156/345.51

(57) ABSTRACT

A clean chemistry composition includes an organic acid and a polar surfactant. The clean chemistry composition is capable of imparting an electrical charge to particles generated during a CMP operation on a wafer made up of semiconductors having a metal gate structure. The imparted electrical charge has the same polarity as that of an electrical charge on the wafer surface, such that the resulting repulsive force between the wafer surface and the newly-charged particles is sufficient to repel the particles from the wafer surface.

### FIELD OF THE INVENTION

The disclosed embodiments of the invention relate generally to wafer cleaning, and relate more particularly to chemistries capable of use in conjunction with chemical mechanical polishing processes.

### BACKGROUND OF THE INVENTION

Chemical mechanical polishing (also called chemical mechanical planarization) (CMP) is a well-established technique in semiconductor fabrication for cleaning and flattening a wafer or other substrate surface. Often the CMP operation, several of which may be performed during the fabrication process, prepares the semiconductor for further processing such as the formation of additional circuit elements. Yet existing CMP processes tend to leave surface particles and other impurities that can pose a significant threat to wafer quality and yield. Small-carbon surface particles, for example, represent a very common defect mode for front-end metal-gate CMP. These particles significantly limit the front-end yield by creating contact shorts and opens. Accordingly, there exists a need for a CMP process in which the negative impact of surface particles is reduced.

### BRIEF DESCRIPTION OF THE DRAWINGS

The disclosed embodiments will be better understood from a reading of the following detailed description, taken in conjunction with the accompanying figures in the drawings in which:

FIG. 1 is a schematic representation of a mechanism for surfactant attachment to an uncharged particle according to an embodiment of the invention;

FIG. 2 is a flowchart illustrating a method of reducing a quantity of particles adhering to a surface having an electrical charge of a first polarity according to an embodiment of the invention;

FIG. 3 is a flowchart illustrating a method of manufacturing a clean chemistry composition according to an embodiment of the invention; and

FIG. 4 is a schematic diagram illustrating a chemical mechanical polish system according to an embodiment of the invention.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used.

### DETAILED DESCRIPTION OF THE DRAWINGS

In one embodiment of the invention, a clean chemistry composition comprises an organic acid and a polar surfactant. The clean chemistry composition is capable of imparting an electrical charge to particles generated during a CMP operation on a wafer having metal gate semiconductors. If the electrical charge given to the particles has the same polarity as that of an electrical charge on the wafer surface, the resulting repulsive force between the wafer surface and the newly-charged particles will be sufficient to repel the particles from the wafer surface. A greater number of the particles may be removed from the wafer surface if the particles are repelled from the wafer surface. The clean chemistry composition thus reduces the negative impact of surface particles on fabrication processes such as front-end metal-gate CMP processes as well as other polish modules such as oxide polish and the like.

Embodiments of the disclosed clean chemistry composition are capable of imparting to such particles a charge of either polarity. Depending on the environment in which such particles are to be removed, a clean chemistry composition may be chosen according to an embodiment of the invention that will impart either a positive or a negative electrical charge, as appropriate.

Wafer surfaces in semiconductor manufacturing typically are negatively charged, which is to say that such surfaces have negative polarity. Accordingly, a clean chemistry composition capable of imparting a negative electrical charge to the particles may be selected, according to an embodiment of the invention. Because electrically charged objects of the same polarity repel each other, particles with negative polarity will be repelled from typical semiconductor wafer surfaces. However, many particles associated with the wafer surface, whether created during a CMP of the surface or otherwise, have no net electrical charge and are thus not naturally repelled from the negatively-charged wafer surface. Such neutral particles are harder to remove than particles having a polarity matching that of the wafer surface. The clean chemistry composition is capable of imparting an electrical charge to these neutral particles, as will be further discussed below.

As an example, the polar surfactant that is a part of the clean chemistry composition may be acid-labile surfactant (ALS), glycolic acid ethoxylate lauryl ether (GAELE), cetyltrimethylammonium bromide (CTAB), or another ionic surfactant. In one embodiment the polar surfactant has a polar part and a non-polar part, where the non-polar part adheres to the particles and the polar part protrudes from a surface of the particles. In order to impart negative polarity to the particles, the polar part of the polar surfactant in at least one embodiment has a negative polarity, i.e., the polar surfactant (or its polar component) is anionic.

It was mentioned above that the clean chemistry composition disclosed herein reduces the negative impact of surface particles on fabrication processes such as front-end metal-gate CMP processes and the like. In one embodiment, the metal gate material is aluminum, the aluminum gate dielectric material is silicon dioxide (SiO₂) having a negative electrical charge, and the surface particles are carbon particles having no initial net electrical charge. As has been discussed, a negative electrical charge is imparted to the carbon particles using the clean chemistry composition such that the carbon particles are repelled from the gate metal surface.

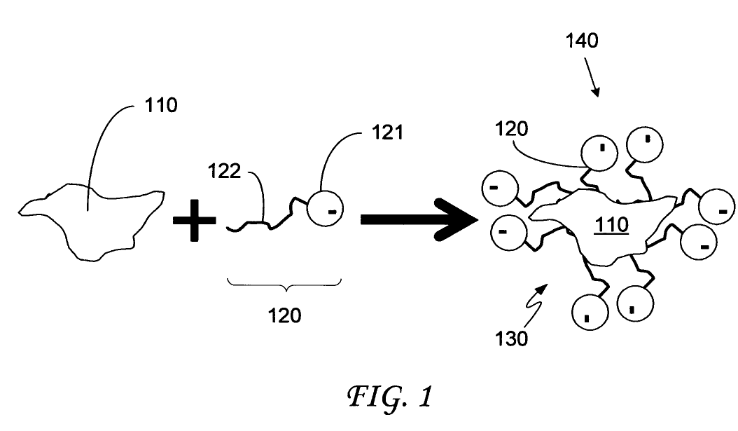

FIG. 1 is a schematic representation of a mechanism for the attachment of a surfactant to an initially uncharged particle according to an embodiment of the invention. As illustrated in FIG. 1, an electrically uncharged particle 110 and a monomer 120 combine to produce an electrically charged particle 130. Monomer 120 is an individual surfactant molecule. When monomer 120 combines with additional monomers, the resulting aggregate of surfactant molecules is known as a micelle. In FIG. 1, a micelle 140 surrounds and attaches to electrically uncharged particle 110, thus creating electrically charged particle 130.

Monomer 120 comprises a polar part 121 and a non-polar part 122, sometimes referred to, respectively, as a head and a tail. As illustrated, non-polar part 122 adheres to electrically uncharged particle 110 and polar part 121 protrudes from a surface of electrically uncharged particle 110 and imparts a surface charge to electrically uncharged particle 110, which then becomes electrically charged particle 130. In one embodiment, electrically uncharged particle 110 is a carbon particle generated in associated with a CMP performed on a metal gate structure, and polar part 121 has a negative electrical charge such that monomer 120 forms part of an anionic surfactant. An anionic surfactant imparts a negative electrical charge to the initially uncharged particles with which it combines, therefore causing such particles to be repelled from a negatively-charged surface. In another embodiment, such as one in which a surface has a positive polarity, a cationic surfactant may be used.

In one embodiment the polar surfactant comprises a polar group having a polarity and a molecular weight. The non-polar part of the polar surfactant comprises a hydrocarbon chain of a particular length. One or more of the polarity, molecular weight, and hydrocarbon chain length of the polar surfactant may be adjusted in order to optimize the surfactant solubility, the adsorption kinetics of the clean chemistry composition, and the like, thus increasing the efficiency of particle removal. As an example, in one embodiment the non-polar part of the polar surfactant adheres to a particle at least in part because a length of the hydrocarbon chain is sufficiently large, and the polar group protrudes from the particle surface at least in part because one or more of the polarity and the molecular weight of the polar surfactant is sufficiently large. Further increases in the removal efficiency may be achieved by adjusting the concentration of one or both of the surfactant and the organic acid in the clean chemistry composition.

In one embodiment, as mentioned above, the clean chemistry composition uses GAELE as the surfactant. As known by one of ordinary skill in the art, a linear formula for GAELE is CH₃(CH₂)₁₁₋₁₃(OCH₂CH₂)ₙOCH₂CO₂H. The CO₂H at the end of the formula represents a carboxylic acid group, which is primarily responsible for GAELE's negative polarity. The OCH₂CH₂ is an ether group, and the subscript n on the ether group indicates that the number of ether groups present in the surfactant molecule may be varied. As an example, the molecular weight of a single GAELE ether group may be approximately 44 grams per mole. The molecular weight for the surfactant as a whole may be adjusted by adjusting the number of repeating ether groups in the formulation. In one embodiment the surfactant molecular weight is adjusted so as to fall between approximately 300 and approximately 900 grams per mole.

Varying the number of repeating ether groups also allows the surfactant concentration to be varied, with possible attendant increases in particle clean efficiency. In one embodiment, the surfactant concentration may vary between approximately 0.01 percent by weight of the clean chemistry composition and approximately 2 percent by weight of the clean chemistry composition. As an example, increasing the number of repeating ether groups in a GAELE structure increases the surfactant solubility, thus allowing a 2 percent concentration to be achieved. Similarly, a decrease in the number of repeating ether groups causes the upper limit of solubility to decrease.

As stated earlier herein, the clean chemistry composition may comprise an organic acid. As an example, the organic acid may be citric acid, acetic acid, oxalic acid, tartaric acid, or the like. In one embodiment, the concentration of organic acid may be between approximately 0.05 moles per liter and approximately 1.0 moles per liter. For the same or another embodiment, the organic acid concentration may be expressed in different terms as being between approximately 0.001 percent by weight and approximately 1.0 percent by weight of the clean chemistry composition. In one or more embodiments, the organic acid comprises a buffered organic acid. The buffered organic acid may be created by using an appropriate counter salt for a particular organic acid, such as, for example, ammonium citrate (among other possibilities) for citric acid. Appropriate counter salts for particular organic acids are well known in the art.

In some embodiments it may be necessary to dilute the acid used in the clean chemistry composition. During such dilution the surface potential (sometimes referred to as the zeta potential or ζ-potential) of the particles may drift, which is an undesirable result. Such change in the surface potential may be prevented or inhibited, and its effects avoided or lessened, if a substantially constant pH for the acid is maintained, and the use of a buffered organic acid makes that possible. In one embodiment, a buffered organic acid may be used to maintain a pH equal or approximately equal to 4.

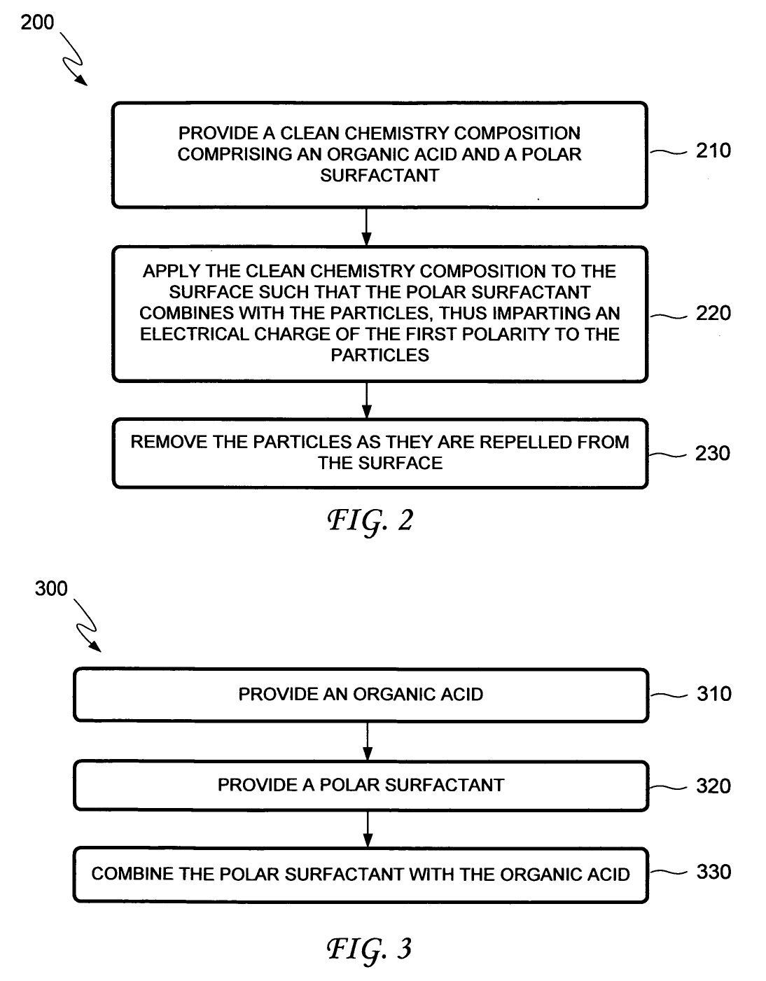

FIG. 2 is a flowchart illustrating a method 200 of reducing a quantity of particles adhering to a surface having an electrical charge of a first polarity according to an embodiment of the invention. In one embodiment method 200 may be performed following a chemical mechanical polish of the surface, which may for example be the surface of a wafer containing transistors having metal gates.

A step 210 of method 200 is to provide a clean chemistry composition comprising an organic acid and a polar surfactant. As an example, the clean chemistry composition, the organic surfactant, and the polar surfactant may be similar to those that have been discussed earlier herein. As a particular example, the polar surfactant may be made up of monomers such as monomer 120, shown in FIG. 1, some of which may be arranged in micelles such as micelle 140, also shown in FIG. 1. In one embodiment, step 210 comprises providing the polar surfactant to have a polar part and a non-polar part. The non-polar part comprises a hydrocarbon chain and the polar part comprises a polar group having a polarity and a molecular weight. As an example, the polar part and the non-polar part can be similar to, respectively, polar part 121 and non-polar part 122, both of which were shown in FIG. 1.

A step 220 of method 200 is to apply the clean chemistry composition to the surface such that the polar surfactant combines with the particles, thus imparting an electrical charge of the first polarity to the particles. As an example, the particles to which the clean chemistry composition is applied can be similar to electrically uncharged particle 110 (shown in FIG. 1) prior to such application, and can be similar to electrically charged particle 130 (also shown in FIG. 1) following such application.

As has been explained above, the surface may have a negative electrical charge such that the first polarity is a negative polarity. In that embodiment step 220 imparts a negative electrical charge to the particles so as to match the negative electrical charge held by the surface. In one embodiment step 220 comprises causing the non-polar part of the polar surfactant to adhere to the particles (which before such adherence have no electrical charge) and further comprises causing the polar part of the polar surfactant to protrude from the particles and thus impart the electrical charge of the first polarity to the particles.

In a particular embodiment, causing the non-polar part of the polar surfactant to adhere to the particles comprises manipulating a length of the hydrocarbon chain. In the same or another embodiment, causing the polar part of the polar surfactant to protrude from the particles comprises manipulating one or more of the polarity and the molecular weight of the polar surfactant.

A step 230 of method 200 is to remove the particles as they are repelled from the surface. As mentioned, the difficulty accompanying such removal is lessened as greater numbers of particles are repelled from the surface, as accomplished, for example, by steps 210 and 220 or another step or steps of method 200.

FIG. 3 is a flowchart illustrating a method 300 of manufacturing a clean chemistry composition according to an embodiment of the invention. A step 310 of method 300 is to provide an organic acid and a step 320 of method 300 is to provide a polar surfactant. In one embodiment, step 320 comprises providing a polar surfactant having a molecular weight between approximately 300 grams per mole and approximately 900 grams per mole. As an example, the organic surfactant and the polar surfactant may be similar to those that have been discussed earlier herein. As an example, in one embodiment step 310 comprises providing a buffered organic acid and in the same or another embodiment step 320 comprises providing a polar surfactant having a polar group.

In one embodiment, step 320 or another step comprises manipulating or varying one or more of a molecular weight (thereby possibly affecting surfactant solubility and/or concentration), a polarity, and a hydrocarbon chain length of the polar surfactant. In one embodiment, such manipulation may be performed in order to control a magnitude of a repulsive force exerted by the surface particles being treated with the clean chemistry composition, thereby controlling the particle clean efficiency.

A step 330 of method 300 is to combine the polar surfactant with the organic acid. In one embodiment, step 330 comprises creating a solution in which a concentration of the polar surfactant is between approximately 0.01 percent by weight of the solution and approximately 2 percent by weight of the solution. In the same or another embodiment, step 330 comprises creating a solution in which a concentration of the organic acid is between approximately 0.001 percent by weight of the solution and approximately 1.0 percent by weight of the solution.

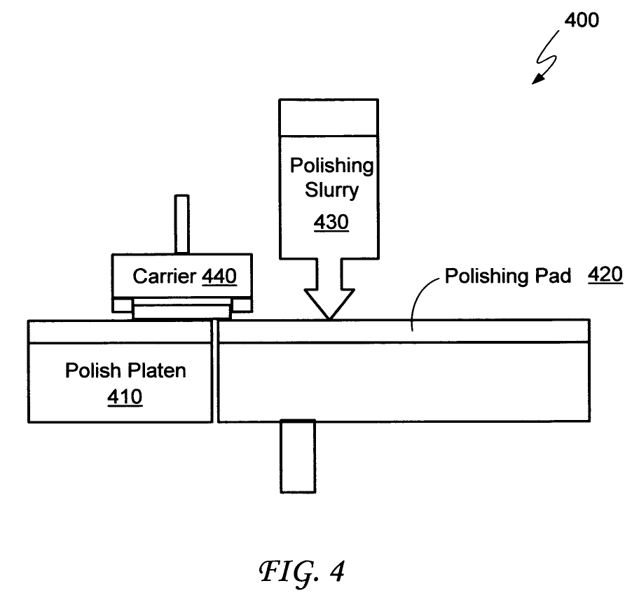

FIG. 4 is a schematic diagram representing a chemical mechanical polish system 400 according to an embodiment of the invention. As illustrated schematically in FIG. 4, chemical mechanical polish system 400 comprises a polish platen 410, a polishing pad 420 affixed to polish platen 410, and a polishing slurry 430 on polishing pad 420. Chemical mechanical polish system 400 further comprises a carrier 440 to hold a wafer or the like (not shown) that will be treated with a CMP procedure. As mentioned above, and as known in the art, CMP processes tend to leave unwanted particles at a surface being subjected to the CMP. Accordingly, polishing slurry 430 comprises a clean chemistry composition comprising an organic acid and a polar surfactant, and is capable of imparting an electrical charge to the surface particles. The clean chemistry composition, the organic surfactant, and the polar surfactant may be similar to those that have been discussed earlier herein. As an example, the clean chemistry composition can be used on polish platen 410 in order to reduce defect generation. Such use reduces wear and tear on polishing pad 420, thereby increasing the useful lifetime of the pad and reducing associated costs.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the clean chemistry composition and associated methods and systems discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A clean chemistry composition capable of mitigating the effect of particles generated during a chemical mechanical polish operation on a metal gate structure, the clean chemistry composition comprising:
an organic acid; and
a polar surfactant,
wherein:
the clean chemistry composition is capable of imparting an electrical charge to the particles.

2. The clean chemistry composition of claim 1 wherein:
the organic acid comprises a buffered organic acid.

3. The clean chemistry composition of claim 2 wherein:
the polar surfactant has a negative polarity.

4. The clean chemistry composition of claim 1 wherein:
each of the particles has a particle surface;
the polar surfactant has a polar part and a non-polar part;
the non-polar part of the polar surfactant adheres to the particles; and
the polar part of the polar surfactant protrudes from the particle surface.

5. The clean chemistry composition of claim 4 wherein:
the polar surfactant comprises a polar group;
the non-polar part of the polar surfactant comprises a hydrocarbon chain;
the polar group has a polarity and a molecular weight;
the non-polar part of the polar surfactant adheres to the particles at least in part because a length of the hydrocarbon chain is sufficiently large; and
the polar part of the polar surfactant protrudes from the particle surface at least in part because one or more of the polarity and the molecular weight of the polar surfactant is sufficiently large.

6. The clean chemistry composition of claim 5 wherein:
the molecular weight of the polar surfactant is between approximately 300 and approximately 900 grams per mole.

7. A clean chemistry composition capable of use with a metal gate material, the clean chemistry composition comprising:
a buffered organic acid; and
an anionic surfactant,
wherein:
the clean chemistry composition is capable of enabling a removal of surface particles from a surface of the metal gate material.

8. The clean chemistry composition of claim 7 wherein:
the metal gate material is aluminum;
the surface of the metal gate material has a negative electrical charge; and
the surface particles are carbon particles having no initial net electrical charge.

9. The clean chemistry composition of claim 8 wherein:
the anionic surfactant comprises a polar group and a hydrocarbon chain;
the hydrocarbon chain adheres to the carbon particles; and
the polar group protrudes from the carbon particles thereby imparting a negative electrical charge to the carbon particles.

10. A method of reducing a quantity of particles adhering to a surface having an electrical charge of a first polarity, the method comprising:
providing a clean chemistry composition comprising an organic acid and a polar surfactant;
applying the clean chemistry composition to the surface such that the polar surfactant combines with the particles, thus imparting an electrical charge of the first polarity to the particles; and
removing the particles as they are repelled from the surface.

11. The method of claim 10 wherein:
providing a clean-chemistry composition comprises providing the polar surfactant to have:
a polar part comprising a polar group having a polarity and a molecular weight; and
a non-polar part comprising a hydrocarbon chain; and
applying the clean chemistry composition comprises:
causing the non-polar part of the polar surfactant to adhere to the particles; and
causing the polar part of the polar surfactant to protrude from the particles and thus impart the electrical charge of the first polarity to the particles.

12. The method of claim 11 wherein:
causing the non-polar part of the polar surfactant to adhere to the particles comprises manipulating a length of the hydrocarbon chain; and
causing the polar part of the polar surfactant to protrude from the particles comprises manipulating one or more of the polarity and the molecular weight of the polar surfactant.

13. The method of claim 11 wherein:
imparting the electrical charge of the first polarity comprises imparting a negative electrical charge to the particles.

14. A method of manufacturing a clean chemistry composition, the method comprising:
providing an organic acid;
providing a polar surfactant; and
combining the polar surfactant with the organic acid.

15. The method of claim 14 wherein:
providing the organic acid comprises providing a buffered organic acid; and
providing the polar surfactant comprises providing the polar surfactant to have a molecular weight between approximately 300 grams per mole and approximately 900 grams per mole.

16. The method of claim 14 wherein:
combining the polar surfactant with the organic acid comprises creating a solution in which a concentration of the polar surfactant is between approximately 0.01 percent by weight of the solution and approximately 2 percent by weight of the solution.

17. The method of claim 16 wherein:
combining the polar surfactant with the organic acid comprises creating a solution in which a concentration of the organic acid is between approximately 0.001 percent by weight of the solution and approximately 1.0 percent by weight of the solution.

18. A chemical mechanical polish system comprising:
a polish platen;
a polishing pad affixed to the polish platen; and
a polishing slurry on the polishing pad,
wherein:
the polish platen, the polishing pad, and the polishing slurry produce particles;
the polishing slurry comprises a clean chemistry composition comprising:
an organic acid; and
a polar surfactant; and
the clean chemistry composition is capable of imparting an electrical charge to the particles.

19. The chemical mechanical polish system of claim 18 wherein:
the organic acid comprises a buffered organic acid;
the polar surfactant has a polar part and a non-polar part; and
the polar surfactant has a negative polarity.

20. The chemical mechanical polish system of claim 19 wherein:
each of the particles has a particle surface;
the polar surfactant comprises a polar group;
the non-polar part of the polar surfactant comprises a hydrocarbon chain;
the polar group has a polarity and a molecular weight;
the non-polar part of the polar surfactant adheres to the particles at least in part because a length of the hydrocarbon chain is sufficiently large; and
the polar part of the polar surfactant protrudes from the particle surface at least in part because one or more of the polarity and the molecular weight of the polar surfactant is sufficiently large.
